(19) United States
(12) Patent Application Publication
(10) Pub. No.: US 2014/0240135 A1
(43) Pub. Date: Aug. 28, 2014

(54) Tornado Warning System

(71) Applicant: John F. Semrau, (US)

(72) Inventor: John F. Semrau, (US)

(21) Appl. No.: 13/358,924

(22) Filed: Jan. 26, 2012

(51) Int. Cl. G08B 21/10; H05K 3/30

(52) U.S. Cl. CPC G08B 21/10; H05K 3/30
USPC 340/626; 29/832

(57) ABSTRACT

A system used to determine the near presence of a tornado and to alert those in the immediate area.

### BACKGROUND OF INVENTION

Measure air pressure to indicate presence of a tornado.

### OBJECT AND ADVANTAGES

This invention will be very helpful in warning of (an immediate/probable) presence of a tornado; only providing a relatively short notice of impending disaster.

### Advantages

Previous to this system being available, there were no known means of a Personal Area Warning System comparable to the commonly present Public Warning Systems, that responds to a larger area that is threatened, managed by local Emergency Management Systems. With the use this Personal Warning System, it is hoped that there will be enough warning provided to those in the immediate area to take immediate actions to protect themselves.

### SUMMARY

This system provides a warning of immediate danger due to the presence of an actual tornado or tornado-like environments.

### Operation

The operation of the unit has been designed to operate with minimal user interaction. The preferred embodiment would have no human interaction beyond plugging the unit in and installing/changing batteries. Due to many unknown variables, there may need to be a source for adjusting the sensitivity of the unit due to too many alerts (false positives or false negatives). Air pressure is measured continually measured. When the change in air pressure relative to time surpasses a threshold, an alarm(s) are sounded to alert anybody in the immediate area. As the threat diminishes, the alarm(s) turn off. Due to the fractal nature of all the variables involved, there can be no statements made of any guarantee of any early warning of threatening weather conditions. This system will hopefully will be a valuable resource to be used with in conjunction with all currently available warning systems/resources.

### DRAWINGS

FIG. 1 is the flowchart of the program that operates and controls the hardware. It starts with the text “Start”, at this point it could of just been plugged in or reset. This process wakes up the system as it begins to watch the sensor(s) for input. Following is an option that can be made available to adjust the sensitivity. The input is read and if it surpasses a set threshold, an initial alarm can be sounded as a pending warning, followed by a possibly louder, louder alarm indicating an imminent danger. After a period of time the alarm turns off, and the process is started over again.

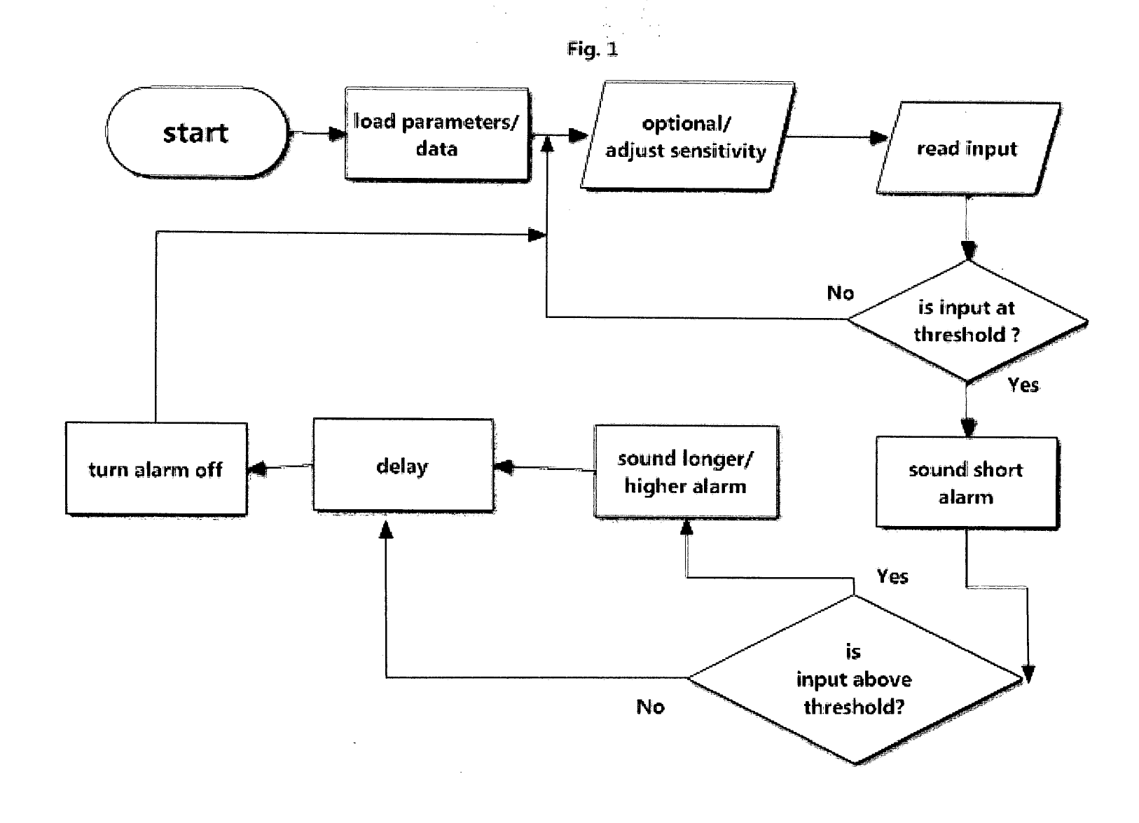

### CONCLUSIONS, RAMIFICATIONS, SCOPE

This unit should provide an early warning of a tornado or threatening environment approximating a tornado. Even though there will not be as large amount of a warning as there are with hurricanes, this unit is designed to alert anybody in close proximity to an immediate threat.

### DETAILED DESCRIPTION

This system/unit becomes functional when it is plugged in and the batteries are installed. The program starts and the sensitivity parameters are calculated. The preferred embodiment does not include an option to adjust the sensitivity, next would be reading the input voltage from the pressure sensor. The input is constantly looped through to compare it to programmed parameters. When the input surpasses a threshold, an alarm(s) is sounded, as further parameters are passed, additional alarm(s) are activated. The reverse procedure is followed as the input decreases and alarm(s) are turned off. A preferred application might be to change the volume and/or frequency of the alarm(s) as threats are encountered.

1. a method of assembling electronic hardware comprising the steps of:
a) a pressure sensing device connected to a configuration of electronic processing hardware, commonly referred to as the motherboard, and
b) a device that is auditable shall be connected to said motherboard for the purpose of transmitting audio signals, and
c) an electrical source to energize said motherboard, and
1) said electrical source comprises utility company and batteries.

2. a machine for monitoring air pressure and producing an alarm composed of:
a) a pressure sensing device that produces a varying electrical output in response to a varying air pressure, and
b) a plurality of electronic components used for the purpose of receiving output from said pressure sensing device and producing an output signal, and
c) said electronic components can include what is commonly referred to as a microcontroller(s), microprocessor(s), common electronic component(s) commonly referred to as motherboard, and
d) a device to receive output from said electrical components to create an alarming signal, comprising of a plurality of electromechanical mechanisms, solid state components.

3. a machine to control the operational logic comprising:
a) parameters are initiated by means of software program, and
b) a starting point, and
c) adjustable, optional controls to modify the input to said software program are incorporated, and
d) if input to said motherboard exceeds preprogrammed thresholds, the said process is passed to the alarm stage, otherwise said software program loops back to starting point of said program, and
e) when said software program is passed to said alarm stage, an alarm or plurality of alarms are utilized depending on the degree that the input exceeds the said preprogrammed thresholds, and
f) said software program returns to said starting point.
